(19) United States
(12) Patent Application Publication
(10) Pub. No.: US 2025/0374728 A1
(43) Pub. Date: Dec. 4, 2025

(54) MICRO-LED MONITORING

(71) Applicant: Google LLC, Mountain View, CA (US)

(72) Inventors: Daniel Adema, Kitchener (CA); Eliezer Glik, San Diego, CA (US); Shreyas Potnis, Kitchener (CA)

(21) Appl. No.: 19/104,063

(22) PCT Filed: Aug. 29, 2023
(86) PCT No.: PCT/US2023/073108

§ 371 Date: Feb. 14, 2025

Related U.S. Application Data
(60) Provisional application No. 63/374,143, filed on Aug. 31, 2022.

(51) Int. Cl. H10H 29/24; H01L 25/16; H10F 55/25; H10H 29/80

(52) U.S. Cl. CPC H10H 29/24; H01L 25/167; H10F 55/25; H10H 29/842; H10H 29/872; H10H 29/882

(57) ABSTRACT

A self-monitoring system for a micro-LED display panel can track a health status of the micro-LED emitters over the life cycle of the display. The self-monitoring system can include, for example, light sensors and a coverglass treated with an anti-reflective coating that directs light emitted by the micro-LED array toward the light sensors. Light captured by the light sensors can then be analyzed to determine the current value of light attributes such as color, polarization, and intensity, and to compare the current values of the light attributes with their previous values to monitor changes over time.

### CROSS-REFERENCE TO RELATED APPLICATION

This application claims the benefit of U.S. Provisional Patent Application No. 63/374,143, filed on Aug. 31, 2022, entitled “MicroLED Color and Intensity Monitoring using Coverglass Pickoff,” the disclosure of which is incorporated by reference herein in its entirety.

### FIELD OF THE DISCLOSURE

The present disclosure relates to display technology and, in particular, to arrays of light emitters for use in displays, including heads-up displays and headsets for virtual reality and augmented reality experiences.

### BACKGROUND

A mobile display device such as a touch screen or a heads-up display may incorporate a pixel grid, or pixel array, of light-producing elements, or emitters. A pixel is an area of illumination on the display, corresponding to the smallest individually addressable element of the display image. Some display devices use, as light sources, sub-micron sized light emitting diodes, or “micro-LEDs.” Each pixel in the array can be formed as a single micro-LED emitter tuned to a specific wavelength, or color, of light e.g., one of the primary light colors-red, green, or blue. Alternatively, each pixel can be formed as a group of micro-LED emitters. The number and arrangement of the constituent micro-LED emitters within a pixel determines the color and intensity of light emission from each pixel in the array, in response to electrical signals applied to the emitters.

### SUMMARY

The present disclosure describes methods and devices that can be used to monitor the light output of a micro-LED display panel over its lifetime. Metrics for light output can include, for example, total light output, color balance, polarization, and output variation across the micro-LED panel. Such measurements are currently made in-factory during initial fabrication and calibration of the micro-LED panel, using external photodiodes and photodetectors. However, it would be desirable to implement an on-board solution to continue monitoring light output during operation of the display for the purpose of life-cycle maintenance.

In some aspects, the techniques described herein relate to an apparatus, including: an array of micro-LED light emitters formed on a semiconductor substrate: light sensors disposed around a periphery of the array; and a coverglass disposed adjacent to the array, the coverglass configured to transmit a first portion of emitted light and to reflect a second portion of the emitted light toward the light sensors.

In some aspects, the techniques described herein relate to a method, including: emitting light from a micro-LED array: directing a portion of the emitted light to sensors disposed around a periphery of the micro-LED array: receiving reflected light at the sensors; and analyzing the reflected light to determine a health status of the micro-LED array.

In some aspects, the techniques described herein relate to a monitoring system, including: a coverglass configured to reflect light from a micro-LED emitter array, light sensors configured to capture the reflected light; and a processor programmed to analyze the reflected light captured by the light sensors and to determine therefrom a state of the micro-LED emitter array.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIGS. 1A, 2A, 3A, 4A, and 5A are top plan views of a micro-LED pixel array equipped with various features to permit self-monitoring, according to various possible implementations of the present disclosure.

FIGS. 1B, 2B, 3B, 4B, and 5B are cross-sectional views of the micro-LED pixel array corresponding to the top plan views, according to various possible implementations of the present disclosure.

FIGS. 6A and 6B are top plan views of micro-LED pixel arrays equipped with wavelength-specific or polarization-specific sensors, according to various possible implementations of the present disclosure.

FIG. 7 is a flow chart for a self-monitoring process to evaluate the health of a micro-LED array, according to a possible implementation of the present disclosure.

FIG. 8 is a system block diagram of a computer system for implementing the self-monitoring process shown in FIG. 7, according to a possible implementation of the present disclosure.

The components in the drawings are not necessarily drawn to scale relative to each other. Like reference numerals designate corresponding parts throughout the several views.

### DETAILED DESCRIPTION

A technical problem with micro-LED display panels, or screens, is that each display panel may degrade over its lifetime such that the overall intensity of the light output decreases, or the light output varies spatially, across the panel. Additionally or alternatively, the color of light produced by the micro-LEDs may change, or the color balance across the pixel array may shift over time. Additionally or alternatively, the polarization of light produced by the micro-LEDs may change, or the polarization balance across the pixel array may shift over time.

One technical solution to address these technical problems is to add a self-monitoring system to the micro-LED display panel to track a health status of the micro-LED emitters over time. The self-monitoring system can include, for example, light sensors and a coverglass treated with an anti-reflective coating that directs light emitted by the micro-LED array toward the light sensors. Light captured by the light sensors can then be analyzed to determine the current value of light attributes such as color, polarization, and intensity, and to compare the current values of the light attributes with their previous values to monitor changes over time.

As used herein, a micro-LED refers to a light-emitting diode having sub-micron dimensions.

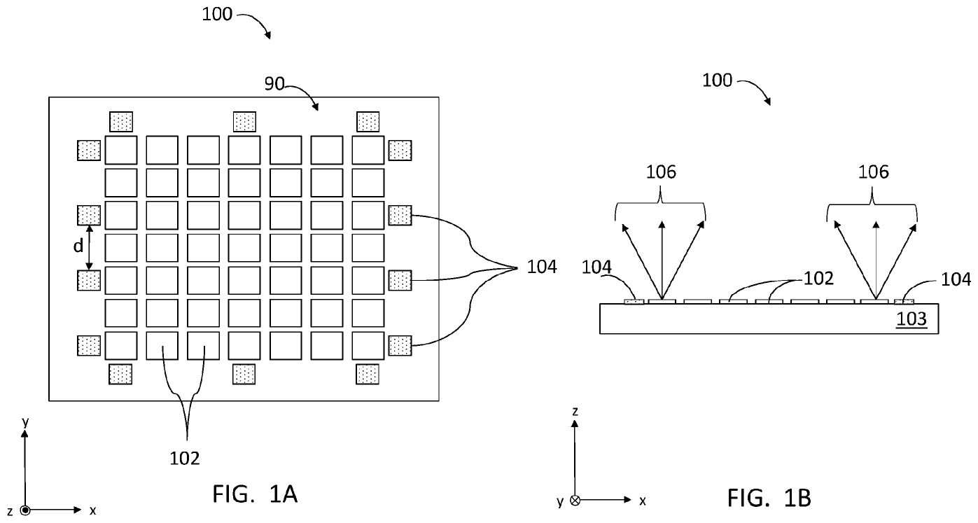

FIGS. 1A and 1B show a top-down plan view and a cross-sectional view, respectively, of a first micro-LED array 100, according to some implementations of the present disclosure. The first micro-LED array 100 includes a pixel matrix 90 of pixels 102, wherein each pixel can include a single monochrome micro-LED emitter or a group of micro-LED emitters, e.g., a group of three emitters, red, green, and blue, that constitute a trichrome pixel. In some implementations, the pixels 102 of the matrix 90 are rectilinear, e.g., aligned in x- and y-directions, and are laid out in a square or rectangular arrangement and fabricated on a substrate 103, as shown in FIG. 1B. Various other layouts of the pixels 102 can be used.

The substrate 103 can include one or more of a wide array of semiconductor materials such as, but not limited to, silicon (Si). In some implementations, the substrate 103 can include (i) an elemental semiconductor, such as germanium (Ge); or (ii) a compound semiconductor such as silicon carbide (SiC), gallium arsenide (GaAs), gallium phosphide (GaP), indium phosphide (InP), or the like. In some implementations, the substrate 103 may include III-nitride materials such as gallium nitride (GaN), indium gallium nitride (InGaN), aluminum gallium nitride (AlGaN) aluminum indium gallium nitride (AlInGaN), and other alloys. Alternatively, the substrate 103 can include an electrically non-conductive material, such as a glass or sapphire wafer, or a plastic substrate.

In some implementations, the micro-LED emitters can be formed monolithically, e.g., all three colors can be formed on a same epitaxial growth semiconductor substrate, e.g., a III-nitride substrate. For example, a semiconductor wafer with a GaN buffer (e.g., on sapphire or silicon or bulk GaN) can be used as an epitaxial growth substrate, and micro-LED emitters of all three colors can be formed on this substrate by a succession of epitaxial growth operations and other processing operations. The semiconductor wafer may further be processed into semiconductor dice that can be attached to a backplane to form displays.

The micro-LED emitters within each pixel 102 can emit red, green, or blue light, depending on the LED source and/or whether or not a color filter is incorporated into each of the pixels 102. In some implementations, each pixel 102 can be about 4 microns on a side, and can be spaced apart by an approximate distance in a range of about 2.0 microns to about 10.0 microns. Emitted light 106 produced by the light emitting diodes is generally directed in a radially isotropic pattern, with respect to the surface of the first micro-LED array 100, as shown in FIG. 1B.

The first micro-LED array 100 is further equipped with light sensors 104 to permit self-monitoring during normal use. The light sensors 104 can be disposed around a periphery of the first micro-LED array 100, e.g., distributed around the perimeter of the first micro-LED array 100 as opposed to being distributed throughout the first micro-LED array 100. The light sensors 104 are positioned to capture a small amount of light emitted at wide angles from the first micro-LED array 100. For an n×n square micro-LED array, the number of light sensors 104 can be about 2n. For example, FIG. 1A illustrates the first micro-LED array 100 as a 7×7 pixel matrix 90 surrounded by 2×7=14 light sensors 104. The number of light sensors to include involves a consideration of the tradeoff between precision of measurement that is afforded by more sensors, vs. higher energy consumption. In some implementations, for example, the light sensors 104 can be silicon photodetectors, e.g., photodiodes that are formed integrally on a silicon substrate together with the micro-LED array, in a same or similar process as is used to form the pixels 102. In some implementations, the light sensors 104 can be discrete components, e.g., silicon photodetectors, that are manufactured separately and then attached to the first micro-LED array 100 using, for example, an optical adhesive. In some implementations, the light sensors 104 can be spaced apart by an approximate distance d, which can be as small as the pixel pitch, or up to about 10 times greater than the pixel pitch. Therefore, in some implementations, adjacent sensors can be spaced apart so there is one sensor for about every 10 pixels. With a geometric distribution of sensors, a malfunctioning pixel can be identified by a process of triangulation.

In some examples, the light sensors 104 are configured to detect light emitted from the pixel matrix 90 of pixels 102. The light sensors 104 receive the light emitted from one or more of the pixels 102, including an intensity of the light. That is, the light sensors 104 measure an intensity of the light emitted from one or more of the pixels 102. The intensity of the light measured by the light sensors 104 may be stored and analyzed to determine changes over time in individual pixels 102 and/or changes in the overall pixel matrix 90 over time, as discussed in more detail below.

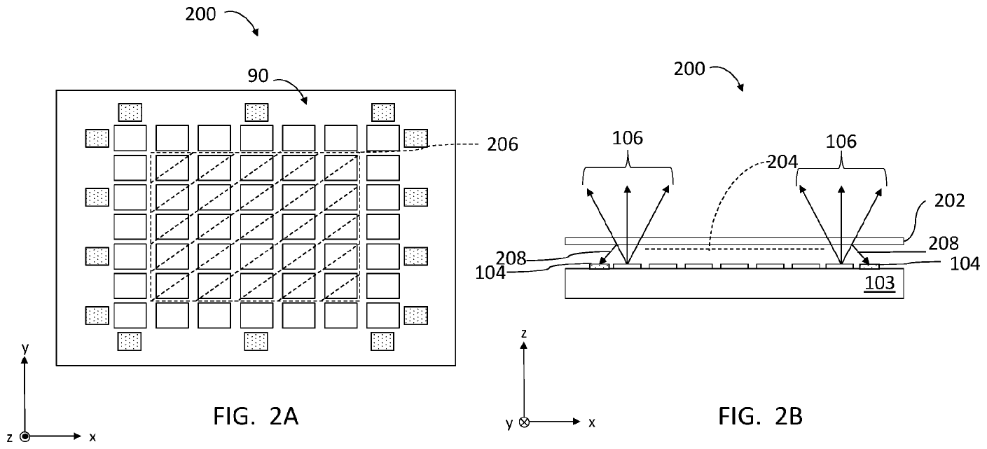

FIGS. 2A and 2B show a top down plan view and a cross-sectional view, respectively, of a second micro-LED array 200, according to some implementations of the present disclosure. The second micro-LED array 200 includes the first micro-LED array 100 equipped with a monitoring system, including the light sensors 104, with the addition of a coverglass 202. In some implementations, the coverglass 202 is spaced apart from the first micro-LED array 100 by a gap in a range of about 100 to about 400 microns. The coverglass 202 can reflect a small fraction of the emitted light that is incident on the coverglass 202. The amount of back-reflected light is a function of the coverglass material. In some implementations, the coverglass 202 can be made of a high quality glass material that can transmit emitted light while protecting the pixels 102 from contamination and damage. The size and/or thickness of the coverglass 202 can be customized. In some implementations, the coverglass 202 can be about 200 microns thick.

In some implementations, the monitoring system further includes an anti-reflective (AR) coating 204. The AR coating 204 can be applied to an underside of the coverglass 202 throughout an AR coated region 206 of the pixel array 90. In some implementations, the AR coated region 206 covers all of the pixel array 90. In some implementations, the AR coated region 206 covers at least a portion of the pixel array 90. For example, the AR coated region 206 can cover an (n−1)×(n−1) area of the pixel array 90. The AR coating 204 can be configured to reflect a prescribed portion of the emitted light 106, directing reflected light 208 toward the light sensors 104. The AR coating 204 can also be configured to permit transmission of a prescribed portion of the emitted light 106, directing transmitted light 106 into the coverglass 202, where the transmitted light 106 can be further directed to the light sensors 104 as described below. The amount of reflected light 208 is a function of the AR coating performance. In some implementations, the AR coating 204 is deposited onto the underside of the coverglass 202 facing the pixel array 90. Alternatively, some AR coatings 204 can be applied using other methods, such as, for example, a spray-on technique. The thickness and the material of the AR coating 204 can be adjusted to achieve a desired index of refraction n, which can determine, or partially determine, the relative transmittance and reflectance of the coating, e.g., what percentage of the emitted light is transmitted by the coverglass 202 and what percentage is reflected by the coverglass 202. Characteristics of the AR coating 204 may also influence the angle and direction of the reflected light 208. Because the light sensors 104 are located around a perimeter of the micro-LED array, additional features described below can be included to further influence the path of the reflected light 208 for efficient capture by the light sensors 104.

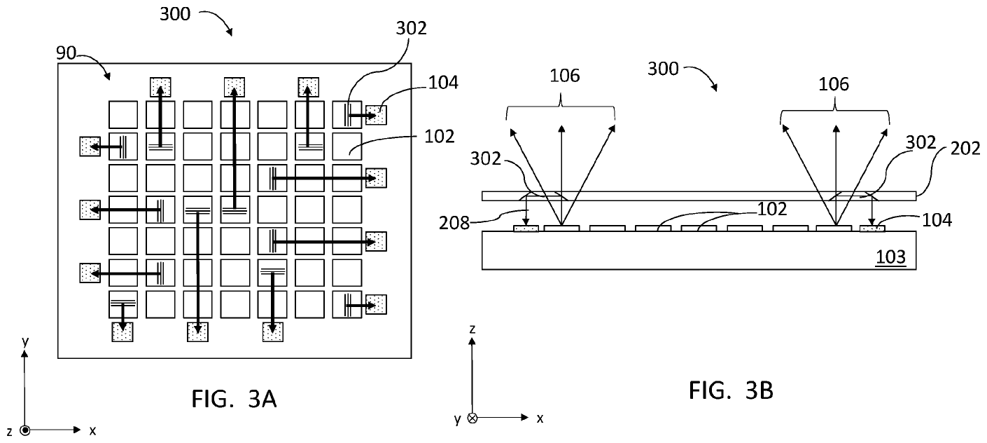

FIGS. 3A and 3B show a top down plan view and a cross-sectional view, respectively, of a third micro-LED array 300, according to some implementations of the present disclosure. The third micro-LED array 300 includes the second micro-LED array 200, wherein the coverglass 202 features gratings 302 formed therein, according to some implementations of the present disclosure. The gratings 302 can further assist in directing light inside the coverglass 202 toward the light sensors 104. For example, the gratings 302 can capture transmitted light rays within the coverglass 202, that otherwise might not be directed toward the light sensors 104.

In some implementations, the gratings 302 can be in the form of weak holographic gratings, wherein a portion of emitted light 106 interacts with the grating 302 and is channeled laterally, within the coverglass 202 as a waveguide, or lightguide. In some implementations, light reflected from the gratings 302 may propagate along a substantially horizontal path within the coverglass 202 and then along a substantially downward vertical path from the coverglass 202 to the light sensors 104.

In some implementations, the gratings 302 can be associated with a subset of the pixels 102, as opposed to all of the pixels 102. Because the pixels 102 are individually addressable a pixel map indicating which pixels have the gratings 302 can be stored in a computer memory. The pixel map can then be used to predict an amount of light energy that the gratings 302 can direct to the light sensors 104. Predictions performed electronically by a microprocessor can then be compared against actual measurements. In some implementations, the gratings 302 can be tuned to select specific colors or polarizations of light from the emitted light 106.

Additionally or alternatively, scattering sites can be added to the coverglass 202 in the form of surface features, embedded features, or particles within the material of the coverglass 202. Similar to the gratings 302, scattering sites serve to couple a portion of the emitted light 106 into the coverglass 202 as a lightguide. In some implementations, the scattering sites can be restricted to selected regions of the coverglass 202.

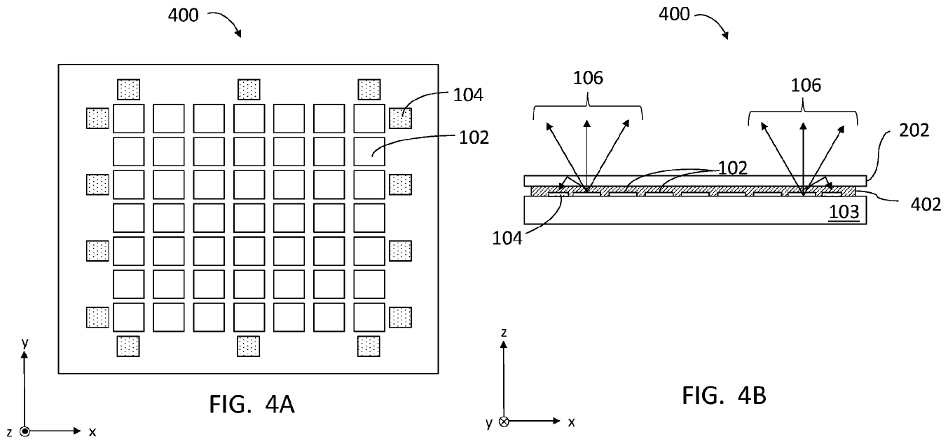

FIGS. 4A and 4B show a top down plan view and a cross-sectional view, respectively, of a fourth micro-LED array 400, according to some implementations of the present disclosure. The fourth micro-LED array 400 includes the second micro-LED array 200 featuring the light sensors 104 and the coverglass 202, with the addition of a bonding agent 402. The bonding agent 402 provides a physical bond between the coverglass 202, the light sensors 104, and the substrate 103. The bonding agent 402 can be, for example, an optical adhesive. The bonding agent 402 fills the gap between the substrate 103 and the coverglass 202, displacing a volume of air from the gap. The presence of the bonding agent 402 can couple light emitted at wide angles, e.g., from edge pixels, into the light sensors 104.

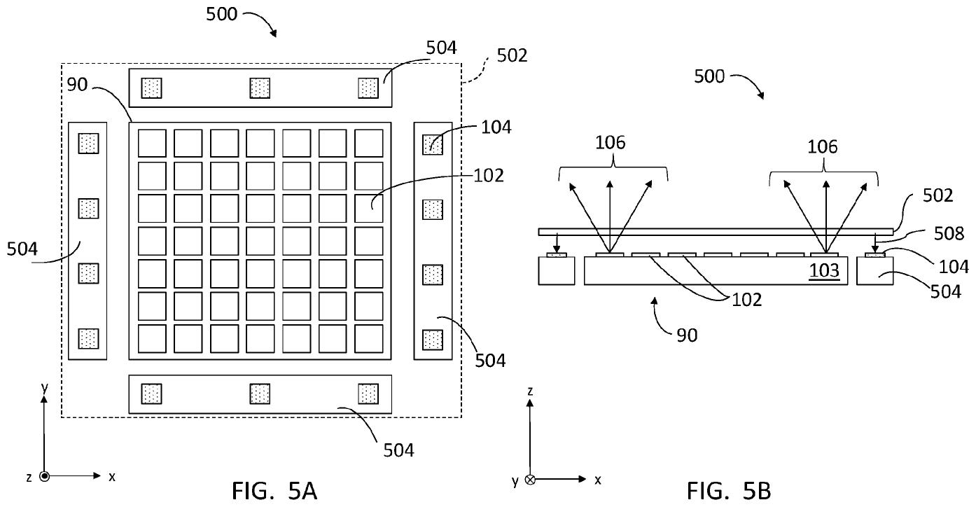

FIGS. 5A and 5B show a top down plan view and a cross-sectional view, respectively, of a fifth micro-LED array 500, according to some implementations of the present disclosure. The fifth micro-LED array 500 includes the pixel matrix 90, an extended coverglass 502, and the light sensors 104. The extended coverglass 502 replaces the coverglass 202 shown and described with respect to the second micro-LED array 200. In some implementations, the light sensors 104 can be formed as four linear sensor arrays 504 aligned with the four sides of the pixel matrix 90. The extended coverglass 502 can be enlarged so as to cover the entire pixel matrix 90 as well as the light sensors 104 arranged in the linear sensor arrays 504. Light that is reflected from the extended coverglass 502. e.g., reflected light 508, can then follow a vertical path from the extended coverglass 502 to the light sensors 104, as shown in FIG. 5B.

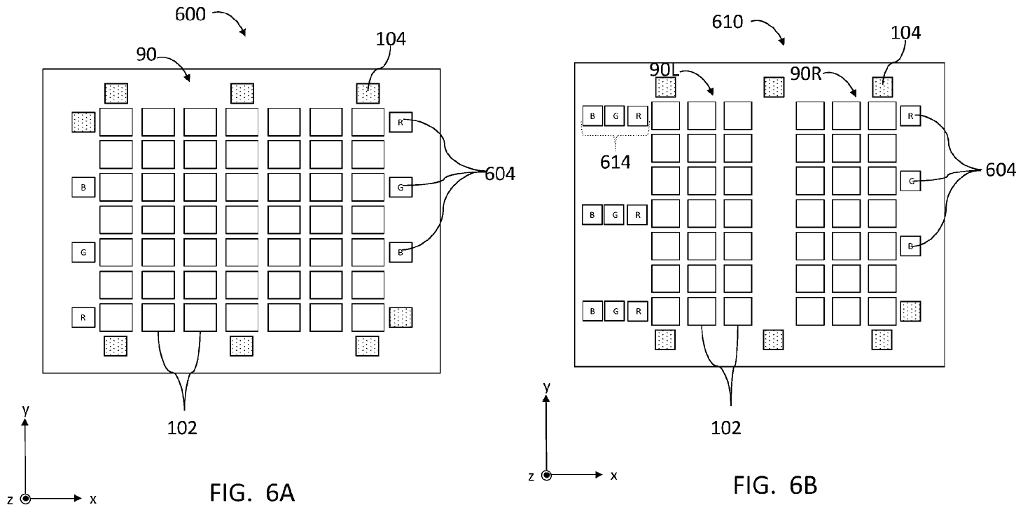

FIGS. 6A and 6B show top down plan views of a sixth micro-LED array 600 and a seventh micro-LED array 610, respectively, equipped with wavelength-specific light sensors 604, according to some implementations of the present disclosure. In some examples, the wavelength-specific light sensors 604, labeled R, G, or B for red, green, or blue, are tuned to detect a specific wavelength within the spectrum of visible light. In some examples, the wavelength-specific light sensors 604 are implemented as light sensors 104 combined with a wavelength filter that selects a specific wavelength of light, or range of wavelengths. Some of the light sensors distributed around the periphery of the pixel matrix 90 can be the wavelength-specific light sensors 604, while others can be the light sensors 104 that are designed to detect all wavelengths of visible light. The wavelength-specific light sensors 604 can be used to test the light intensity of different colors either sequentially or in parallel, according to instructions executed by the computing system 800.

In some implementations, one or more of the wavelength-specific light sensors 604 can be replaced by a polarization-specific light sensor that is either tuned to a specific polarization of light, or that includes a polarization filter to select a specific polarization, e.g., horizontal polarization, vertical polarization, or circular polarization, of light incident on the sensor, while the light sensors 104 are designed to receive all polarizations of light.

In FIG. 6B, the seventh micro-LED array 610 includes a pixel matrix 90 that is divided into a left pixel matrix portion 90L and a right pixel matrix portion 90R. The right pixel matrix portion 90R includes some light sensors 104 and some wavelength-specific light sensors 604. The left pixel matrix portion 90L includes some light sensors 104 and some wavelength-specific light sensors 604 that are grouped into light sensor triads 614. In some implementations, each light sensor triad 614 (three shown) can include all three varieties (R, G, and B) of wavelength-specific light sensors 604. In some implementations, the light sensor triad 614 can include a mix of color-specific and/or polarization-specific light sensors.

Additional implementations of micro-LED arrays can include various combinations of features from the first micro-LED array 100, the second micro-LED array 200, the third micro-LED array 300, the fourth micro-LED array 400, the fifth micro-LED array 500, the sixth micro-LED array 600, and the seventh micro-LED array 610.

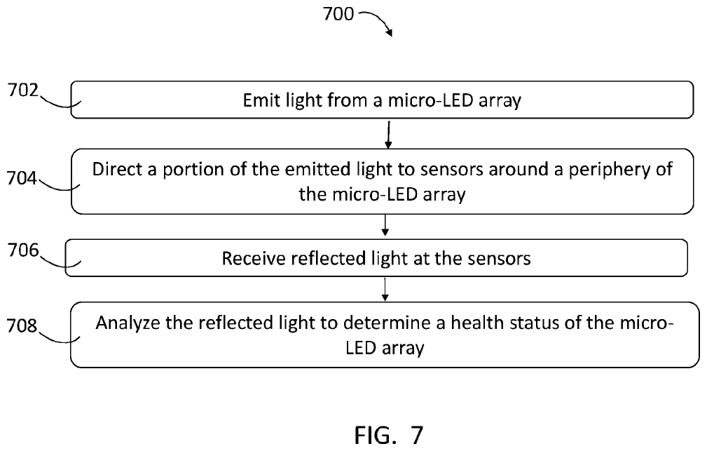

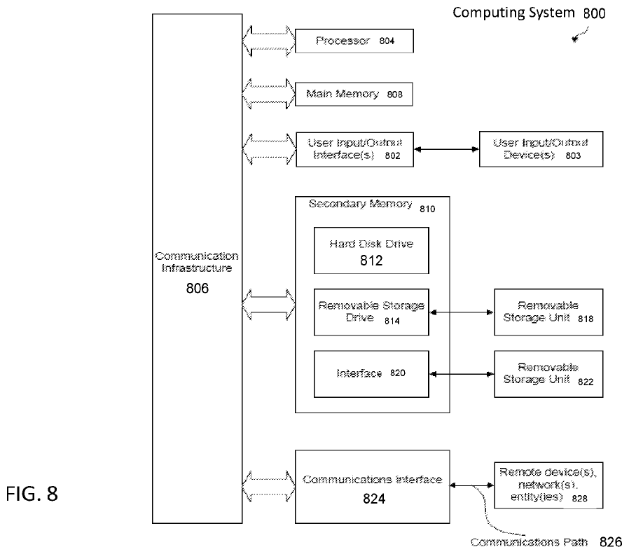

FIG. 7 is a flow chart illustrating a method 700 of self-monitoring a micro-LED array, according to some implementations of the present disclosure. Operations of the method 700 can be performed in a different order, or not performed, depending on specific applications. It is noted that the method 700 may not be a comprehensive self-monitoring process. Accordingly, it is understood that additional processes can be provided before, during, or after the method 700, and that some of these additional processes may be briefly described herein. The operations 702-708 can be carried out by a monitoring system, to monitor the micro-LED array over time, according to the implementations described above, with reference to FIGS. 1A, 1B, 2A, 2B, 3A, 3B, 4A, 4B, 5A, 5B, 6A, 6B, and with reference to a computing system 800 as shown in FIG. 8 and described below. In some implementations, the method 700 can improve sensing and analyzing light emissions over previous methods. For example, a baseline calibration procedure can be carried out to record initial factory settings. A calibration sensor map can be generated by illuminating each pixel sequentially, and recording intensity values for each of the RGB color components. Then, at start-up, and on a schedule, e.g., monthly or quarterly, a similar sensor map can be recorded and compared with the calibration standard sensor map to verify charge characteristics of each pixel.

At 702, the method 700 includes emitting light from a micro-LED array, e.g., from one or more of the micro-LED arrays 100, 200, 300, 400, 500, 600, or 610, according to some implementations of the present disclosure. The emitted light 106 follows radial paths, isotropically outward from each emitter within each pixel 102. Light emission can be initiated, e.g., switched on or off, via a computing system 800 coupled to the micro-LED array. In some implementations, the computing system 800 can be a type of computer system that provides feedback based on sensor input from the light sensors 104 and/or the wavelength-specific light sensors 604. Emitting light from the micro-LED array can be done in a pixel-by-pixel fashion so as to be comparable against the standard established at the time of manufacturing.

At 704, the method 700 includes directing a portion of the emitted light 106 to sensors, e.g., to the light sensors 104 and/or to the wavelength-specific light sensors 604, around a periphery of the micro-LED array, according to some implementations of the present disclosure. Different examples of the micro-LED array are implemented with various features to assist in directing the emitted light 106 to the various light sensors. Therefore, directing a portion of the emitted light 106 may entail use of the AR coating 204, in the case of the second micro-LED array 200, or use of the gratings 302 in the case of the third micro-LED array 300, or use of the bonding agent 402 in the case of the fourth micro-LED array 400.

At 706, the method 700 includes receiving reflected light, e.g., the reflected light 208 or the reflected light 508, at various sensors, according to some implementations of the present disclosure. Receiving the reflected light 208 or the reflected light 508 can further include filtering the reflected light based on wavelength or polarization, and directing selected colors of light, or selected polarizations of light to the light sensors. The light sensors receiving the reflected light can be, for example, the light sensors 104, or the wavelength-specific light sensors 604, implemented with either wavelength-specific sensing elements, or wavelength filters. Alternatively, the sensors receiving the reflected light can be polarization-specific sensors implemented with either polarization-specific sensing elements or polarization filters. Signals from the light sensors 104 or the wavelength-specific light sensors 604, representing intensities and characteristics of the sensed light can then be transmitted to the computing system 800 via a communications interface 824, wherein the light sensors are examples of remote devices 828.

At 708, the method 700 includes analyzing the reflected light 208 and/or the reflected light 508 to determine a state of the micro-LED array, according to some implementations of the present disclosure. Analysis of the reflected light can be carried out by the computing system 800 according to analysis instructions, e.g., analysis software stored in a memory, e.g., the main memory 808 or the secondary memory 810, for execution by the processor 804. The analysis of the reflected light collected by the various sensors can be stored in the secondary memory 810, and compared with previous analysis data for the same micro-LED array. By comparing the data generated at different times during the life cycle of the micro-LED array, trends can be identified, and a health status of the micro-LED array can be determined, based on whether or not the micro-LED array pixels function as expected. For example, light intensity values, color intensity values, or polarization values can be monitored over time for the same sensor location to determine temporal patterns, or at different sensor locations to establish spatial patterns across the micro-LED array. In particular, intensity values can be compared against the initial calibration sensor map to determine whether the pixel brightness of the overall micro-LED array has decreased over time, whether the spatial uniformity of pixel brightness across the array has changed, or whether the color uniformity has changed. For example, if the relative intensity of the red, green, and blue components has diverged over time, then the white light may not receive equal contributions from the three colors and therefore may not appear as white. Once the health status of the micro-LED array has been determined, it is possible to “repair” individual pixels by adjusting the drive characteristics during operation of the array. That is, to compensate for reduced intensity, individual pixels can receive more or less drive power to restore the spatial uniformity or color uniformity of the array. In some cases, an array may be set initially at a reduced brightness, e.g., 75% brightness, to allow for drive power adjustments later. Adjustments can also be made depending on the user. Users may establish different calibration standards based on content or eye sensitivity, for example.

FIG. 8 is an illustration of an example computing system 800 in which various embodiments of the present disclosure can be implemented. The computing system 800 can be any well-known computing system capable of performing the functions and operations described herein. For example, and without limitation, the computing system 800 can provide a hardware platform for implementing the micro-LED array monitoring scheme described above. The computing system 800 can be used, for example, to execute one or more operations in the method 700, which describes an example method for self-monitoring a micro-LED array. In some implementations, the computing system 800 can be fabricated on the same substrate as the micro-LED array being monitored. In some implementations, the computing system 800 can be a separate apparatus that is coupled to the light sensors to monitor the micro-LED array, and to report measurements and/or analysis data characterizing the operations and behavior of the micro-LED array.

The computing system 800 includes one or more processors (also called central processing units, or CPUs), such as a processor 804. The processor 804 is connected to a communication infrastructure or bus 806. The computing system 800 also includes input/output device(s) 803, such as monitors, keyboards, pointing devices, etc., that communicate with a communication infrastructure or bus 806 through input/output interface(s) 802. The processor 804 can receive instructions to implement functions and operations described herein—e.g., method 700 of FIG. 7—via input/output device(s) 803. The computing system 800 also includes a primary or main memory 808, such as random access memory (RAM). The main memory 808 can include one or more levels of cache. The main memory 808 has stored therein control logic (e.g., computer software) and/or data. In some embodiments, the control logic (e.g., computer software) and/or data can include one or more of the operations described above with respect to the method 700 of FIG. 7.

The computing system 800 can also include one or more secondary storage devices or secondary memory 810. The secondary memory 810 can include, for example, a hard disk drive 812 and/or a removable storage device or drive 814. The removable storage drive 814 can be a floppy disk drive, a magnetic tape drive, a compact disk drive, an optical storage device, tape backup device, and/or any other storage device/drive.

The removable storage drive 814 can interact with a removable storage unit 818. The removable storage unit 818 includes a computer usable or readable storage device having stored thereon computer software (control logic) and/or data. The removable storage unit 818 can be a floppy disk, magnetic tape, compact disk, DVD, optical storage disk, thumb drive, and/or any other computer data storage device. The removable storage drive 814 reads from and/or writes to removable storage unit 818 in a well-known manner.

According to some embodiments, the secondary memory 810 can include other means, instrumentalities or other approaches for allowing computer programs and/or other instructions and/or data to be accessed by the computing system 800. Such means, instrumentalities or other approaches can include, for example, a removable storage unit 822 and an interface 820. Examples of the removable storage unit 822 and the interface 820 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, the secondary memory 810, the removable storage unit 818, and/or the removable storage unit 822 can include one or more of the operations described above with respect to the method 700 of FIG. 7.

The computing system 800 can further include a communication or network interface 824. The communications interface 824 enables the computing system 800 to communicate and interact with any combination of remote devices, remote networks, remote entities, etc. (individually and collectively referenced by remote devices 828). For example, the communication interface 824 can allow the computing system 800 to communicate with the remote devices 828 over a communications path 826, which can be wired and/or wireless, and which can include any combination of LANs, WANs, the Internet, etc. Control logic and/or data can be transmitted to and from the computing system 800 via the communications path 826.

The operations in the preceding embodiments can be implemented in a wide variety of configurations and architectures. Therefore, some or all of the operations in the preceding embodiments—e.g., the method 700 of FIG. 7—can be performed in hardware, in software or both. In some embodiments, a tangible apparatus or article of manufacture comprising a tangible computer useable or readable medium having control logic (software) stored thereon is also referred to herein as a computer program product or program storage device. This includes, but is not limited to, the computing system 800, the main memory 808, the secondary memory 810 and the removable storage units 818 and 822, as well as tangible articles of manufacture embodying any combination of the foregoing. Such control logic, when executed by one or more data processing devices (such as the computing system 800), causes such data processing devices to operate as described herein.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about.” it will be understood that the particular value forms another aspect. It will be further understood that the endpoints of each of the ranges are significant both in relation to the other endpoint, and independently of the other endpoint.

As used in this specification, a singular form may, unless definitely indicating a particular case in terms of the context, include a plural form. Spatially relative terms (e.g., “over,” “above,” “upper,” “under,” “beneath,” “below,” “lower,” and so forth) may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some implementations, the relative terms above and below can, respectively, include vertically above and vertically below. In some implementations, the term “adjacent” can include laterally adjacent to or horizontally adjacent to.

In some implementations of the present disclosure, the terms “about” and “substantially” can indicate a value of a given quantity that varies within 20% of the value (for example, ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

Some implementations may be executed using various semiconductor processing and/or packaging techniques. Some implementations may be executed using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

It is to be appreciated that the Detailed Description section, and not the Abstract section, is intended to be used to interpret the claims. The Abstract section may set forth one or more but not all possible embodiments of the present disclosure as contemplated by the inventor(s), and thus, are not intended to limit the subjoined claims in any way.

1. An apparatus, comprising:
an array of micro-LED light emitters formed on a semiconductor substrate;
light sensors disposed around a periphery of the array; and
a coverglass disposed adjacent to the array, the coverglass configured to direct a portion of emitted light toward the light sensors.

2. The apparatus of claim 1, wherein a side of the coverglass facing the array is at least partially coated with an anti-reflective coating (AR coating) to permit transmission of light through a coated portion of the coverglass.

3. The apparatus of claim 2, wherein the AR coating covers a central region of the coverglass, opposite a region of the array.

4. The apparatus of claim 1, further comprising scattering sites in the coverglass, the scattering sites configured to couple a portion of the emitted light into the coverglass for use as a lightguide.

5. The apparatus of claim 4, wherein the lightguide is configured to direct light from a central region of the coverglass to edge regions of the coverglass, for reflection toward the light sensors.

6. The apparatus of claim 1, further comprising a grating in the coverglass, the grating configured to direct light from the coverglass to the light sensors.

7. The apparatus of claim 6, wherein the grating is a holographic grating.

8. The apparatus of claim 1, wherein the coverglass is bonded to the array using an optical adhesive.

9. The apparatus of claim 1, wherein the light sensors are arranged in arrays.

10. The apparatus of claim 1, wherein the light sensors are silicon photodetectors formed on the semiconductor substrate together with the array.

11. A method, comprising:
emitting light from a micro-LED array;
directing, by a coverglass disposed adjacent to the micro-LED array, a portion of the light to sensors disposed around a periphery of the micro-LED array; and
receiving the portion of the light at the sensors.

12. The method of claim 11, further comprising filtering wavelengths of emitted light and receiving selected colors of light at the sensors.

13. The method of claim 11, further comprising filtering polarizations of emitted light and receiving selected polarizations of light at the sensors.

14. The method of claim 11, further comprising analyzing the portion of the light received at the sensors to determine a health status of the micro-LED array.

15. The method of claim 14, wherein the analyzing monitors a color balance status of the micro-LED array.

16. The method of claim 14, wherein the analyzing monitors an intensity status of the micro-LED array.

17. The method of claim 11, wherein directing a portion of the light to the sensors includes reflecting the light toward the sensors, by the coverglass.

18. The method of claim 11, wherein the coverglass includes a grating configured to direct a portion of the light to the sensors.

19. The method of claim 11, further comprising coating a side of the coverglass at least partially with an anti-reflective coating (AR coating) to permit transmission of light through a coated portion of the coverglass.

20. The method of claim 19, wherein the AR coating covers a central region of the coverglass, corresponding to a region of the micro-LED array.

21. The method of claim 11, further comprising providing scattering sites in the coverglass, the scattering sites configured to couple a portion of emitted light into the coverglass for use as a lightguide.

22. The method of claim 21, wherein the lightguide is configured to direct light from a central region of the coverglass to edge regions of the coverglass, for reflection toward the sensors.

23. A monitoring system, comprising:
a coverglass configured to reflect light from a micro-LED emitter array,
light sensors configured to capture reflected light; and
a processor programmed to analyze the reflected light captured by the light sensors and to determine a state of the micro-LED emitter array.

24. The monitoring system of claim 23, wherein the coverglass covers the micro-LED emitter array and the light sensors.

25. The monitoring system of claim 23, wherein the light sensors are equipped with color filters.

26. The monitoring system of claim 23, wherein the light sensors are configured to detect a specific color of light.

27. The monitoring system of claim 23, wherein the light sensors are configured to detect a specific polarization of light.
